(19) United States
(12) Patent Application Publication
(10) Pub. No.: US 2013/0107156 A1
(43) Pub. Date: May 2, 2013

(54) Backplane, Back Light Module and Liquid Crystal Display Device

(71) Applicant: Gege Zhou, Shenzhen (CN)

(72) Inventor: Gege Zhou, Shenzhen (CN)

(21) Appl. No.: 13/375,372

(22) PCT Filed: Oct. 31, 2011
(86) PCT No.: PCT/CN2011/081591

§ 371 Date: Nov. 30, 2011

(30) Foreign Application Priority Data
Oct. 27, 2011 (CN) 201110331325.4

(51) Int. Cl. G02F 1/1333; G09F 13/04; H05K 7/00

(52) U.S. Cl. 349/58; 361/748; 362/97.1

(57) ABSTRACT

The invention discloses a backplane, a back light module, and an LCD device. The backplane comprises a backplane surface and side walls arranged on the sides of the backplane surface. The backplane further comprises at least one layer of stacked plate fixed to the side walls in a stacked mode. Because the side walls of the backplane of the invention are provided with at least one layer of stacked plate fixed to the side walls in stacked mode, the thickness of each side wall of the backplane is increased and thus reinforces the strength of each side wall, and the total strength of the backplane is reinforced under the support of the side walls and the stacked plates thereof. Besides, that the strength of the side walls is reinforced avoides the arrangement of stiffeners on the backplane surface, which reduces the total thickness of the backplane. Thus, on one hand, the total strength of the backplane is guaranteed, on the other hand, it is possible to reduce the thickness of the backplane and make a thinner LCD device.

### TECHNICAL FIELD

The invention relates to the field of liquid crystal displays, and more particularly to a backplane, back light module, and liquid crystal display (LCD) device.

### BACKGROUND

A back light module is one of the critical components of an LCD panel, with function of providing a light source having enough brightness and uniform distribution so that an LCD device can display the image normally.

As shown in FIG. 1, a liquid crystal back light module generally includes a front frame 1, a light guide plate 3, a light source 4, rubber frames 5, a backplane 6, and a PCB panel, etc. An LCD panel 2 is arranged on the back light module. The backplane structure is shown in FIG. 2. The backplane is rectangular and includes four side walls 61. Furthermore, protrusion and depression structures are arranged on the backplane to install other components and reinforce the strength of the backplane. All the main components of the back light module are fixed on the backplane 6. Therefore, the backplane 6, together with the side walls thereof, should have cut structures, hillock structures, and bud structures, etc. (as shown in FIG. 2). Because the side walls of the backplane 6 are in bend-like shapes with respect to the backplane surface, the total strength of the backplane is reinforced. However, because the backplane is provided with cut structures, hillock structures, and bud structures, etc., the strength of the side walls is substantially weakened and so is the total strength of the backplane. As shown in FIG. 2, a dotted line indicates the deformation trend of a backplane in a drop impact test. If the backplane deforms, the components of the module will be damaged or the display effect of the display becomes poor.

Chinese Utility Model Patent No. CN201548778U discloses a liquid crystal module backplane. The total strength of the backplane is reinforced by stiffeners. To reinforce the backplane strength, the utility model adopts the following technical schemes: the stiffeners are arranged on the backplane surface. The stifferners are strong and support the backplane and thus increase the strength of the backplane. The stiffening mode is to reinforce the total strength of the backplane by reinforcing the strength of the backplane surface. Although the consumption of the backplane materials is reduced, protrusion structures appear on the backplane and thus increase the total thickness of the backplane.

### SUMMARY

One aim of the invention is to provide a backplane with high strength as well as a back light module and an LCD device comprising the backplane.

The aim of the invention is achieved by the following technical schemes. A backplane comprises a backplane surface and side walls arranged on the sides of the backplane surface, wherein the backplane further comprises at least one layer of stacked plate fixed to the side walls in a stacked mode.

Preferably, the stacked plate is formed through the bending of the side walls. The stacked plate formed through the bending of the side walls do not require the assembling process of the stacked plates. Because the stacked plate is formed by the side walls, both the stacked plate and the bending reinforce the strength.

Preferably, the height of the stacked plate corresponds to the height of each side wall. The height of the stacked plate is ensured not to exceed that of each side wall to prevent influencing the installation of other components, and the stacked plate should have enough width so that the strength of the stacked plate is enough.

Preferably, the backplane comprises one layer of stacked plate. A single layer of stacked plate can meet the strength requirement and will not occupy too much space of the backplane.

Preferably, the stacked plate is arranged on two side walls facing each other. The stacked plate is arranged on two side walls of the backplane facing each other so that the total strength of the backplane is reinforced.

Preferably, the stacked plate is arranged on all side walls of the backplane. Thus, the strength of all four side walls of the backplane is reinforced, which further reinforces the total strength of the backplane.

Preferably, the stacked plate is arranged on the outer surfaces of the side walls. The outer surfaces are easy to process.

Preferably, the backplane is a plastic structure, and the stacked plate is a metal plate. The strength of the plastic backplane is reinforced using the metal plate, and thus the strength of the plastic backplane is reinforced.

A back light module of the invention is achieved by the following technical scheme. The back light module comprises the aforementioned backplane.

An LCD device of the invention is achieved by the following technical scheme. The LCD device comprises the aforementioned back light module.

Because the side wall of the backplane of the invention is provided with at least one layer of stacked plate fixed to the side wall in stacked mode, the thickness of each side wall of the backplane is increased, and so does the strength of each side wall. The total strength of the backplane is reinforced under the support of the side walls and the stacked plates thereof. Besides, that the strength of the side walls is reinforced avoides the arrangement of stiffeners on the backplane surface, which reduces the total thickness of the backplane. Thus, on one hand, the total strength of the backplane is guaranteed, on the other hand, it is possible to reduce the thickness of the backplane and make a thinner LCD device.

### BRIEF DESCRIPTION OF FIGURES

FIG. 1 is a position assembly diagram and sectional view of an existing backplane in an LCD device;

FIG. 2 is a schematic diagram of deformation trend of an existing backplane in a drop impact test;

FIG. 3 is a sectional view of a structure of one embodiment of the invention; and

FIG. 4 is an assembly diagram and sectional view of a backplane of one embodiment of the invention in an LCD device.

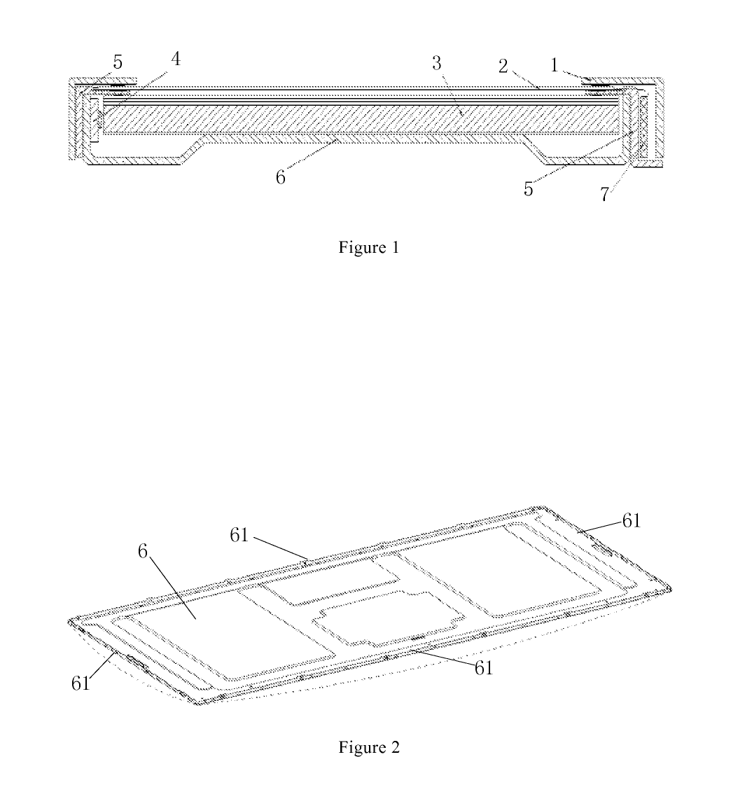

Wherein: 1. Front frame; 2. LCD panel; 3. Light guide plate; 4. Light source; 5. Rubber frame; 6. Backplane; 7. PCB panel; 61. Side wall; 62. Stacked plate.

### DETAILED DESCRIPTION

The invention will further be described in detail in accordance with the figures and the preferred embodiments.

Generally, a backplane is of a slotted structure and the sides thereof are arranged with side walls. The function of the side walls is for installation of other components of a back light module. Additionally, the side walls also reinforce the total strength of the backplane. The invention can further enhance the reinforcing role of the side walls to further reinforce the total strength of the backplane. Thus the backplane can meet the strength requirement under the condition that the thickness of the backplane is decreased and thus the material cost is saved. Specifically, another layer of stacked plate is added onto the side walls of the backplane to increase the thickness of each side wall of the backplane and reinforce the strength of each side wall. Thus, the total reinforcing role of the side walls on the backplane is enhanced, and the total strength of the backplane is reinforced.

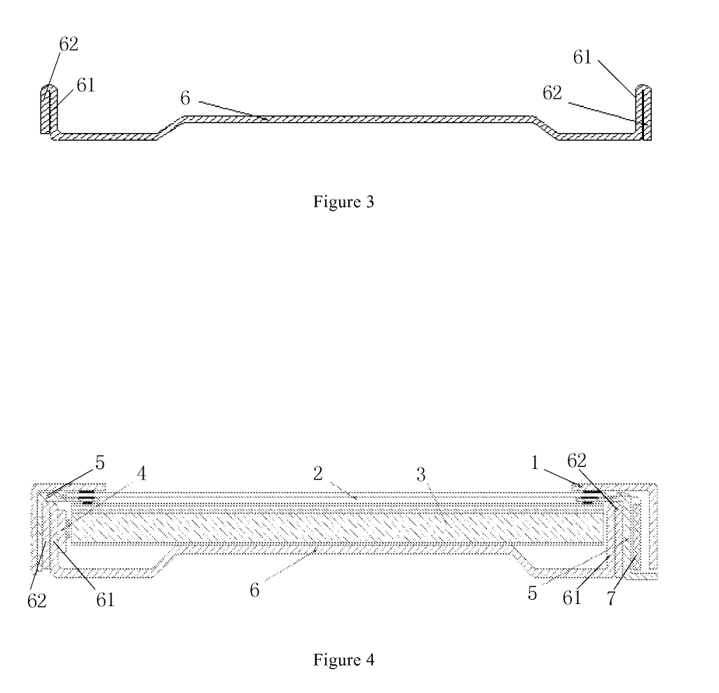

FIG. 3 and FIG. 4 show one embodiment of the invention. As shown in the figures, the backplane 6 is entirely in a slotted structure; the side walls 61 are respectively arranged on the sides of the backplane; and the side walls 61 and the backplane 6 are integrally formed. A stacked plate 62 is arranged on the outer sides of each side wall 61 in a stacked mode. The stacked plate 62 is a folded edge formed by the direct bending of the side wall 61. Optionally, the stacked plate can also be an individual part fixed to the side wall 61 in a stacked mode using screws, rivets, glues and others. The stacked plates 62 (i.e. the folded edge) formed by the direct bending of the side walls are structurally better than other mode (i.e. the mode of locking or splicing the stacked plate that is individually used as a component). The stacked plates 62 formed by the bending and the side walls 61 are integrally formed, and the stacked plates 62 are linked to the side walls 61 through the bends. The bend structures form circular transitions at the bends. Generally, the circular transitions have a high strength, for example, the strength of a circular column is higher than that of a rectangular column.

In the embodiment, the stacked plates 62 may be multiple layers or only one layer. As long as the strength is guaranteed, one layer of stacked plate is preferable, so that the side walls of the backplane 6 is not too thick, thereby preventing the non-display area at the edge of the module from being too wide. At the same time, the width of each stacked plate 62 is equal to the height of each side wall. Thus, the strength of the stacked plates 62 is guaranteed, avoiding that the installation of other components in the back light module is influenced by the much wide stacked plate 62. The stacked plates 62 can be arranged on the outer surfaces as well as the inner surfaces of the side walls 61. However, the stacked plates arranged on the outer surfaces are easier to process or assemble than that of the stacked plates arranged on the inner surfaces. The stacked plates can be arranged only on two side walls 61 facing each other of the backplane 6 as long as the strength requirement is met. Optionally, it is preferable to install the stacked plates 62 at all four side walls so that the strength of the backplane 6 can be reinforced in length and width directions.

Besides, for some backplanes made of plastic materials, the strength thereof can be reinforced by providing stacked plates made of high strength materials, such as metals. Thus, a great deal of material cost is saved.

The invention is described in detail in accordance with the above contents with the specific preferred embodiments. However, this invention is not limited to the specific embodiments. For the ordinary technical personnel of the technical field of the invention, on the premise of keeping the conception of the invention, the technical personnel can also make simple deductions or replacements, and all of which should be considered to belong to the protection scope of the invention.

1. A backplane, comprising: a backplane surface, side walls arranged on the sides of the backplane surface, and at least one layer of stacked plate fixed to said side walls in a stacked mode.

2. The backplane of claim 1, wherein said stacked plate is folded edges formed by the bending of the side walls.

3. The backplane of claim 1, wherein the height of said stacked plate corresponds to that of said side walls.

4. The backplane of claim 1, wherein said backplane comprises one layer of stacked plate.

5. The backplane of claim 1, wherein said stacked plate is arranged on two side walls facing each other.

6. The backplane of claim 1, wherein said stacked plate is arranged on all side walls of said backplane.

7. The backplane of claim 1, wherein said stacked plate is arranged on the outer surfaces of the side walls.

8. The backplane of claim 1, wherein said backplane is a plastic backplane and said stacked plate is a metal plate.

9. A back light module comprises the backplane of claim 1, said backplane comprises the backplane surface, the side walls arranged on the sides of the backplane surface, and at least one layer of stacked plate fixed to said side walls in a stacked mode.

10. The back light module of claim 9, wherein said stacked plate is folded edges formed by bending of the side walls.

11. The back light module of claim 9, wherein the height of said stacked plate corresponds to that of said side wall.

12. The back light module of claim 9, wherein said backplane comprises one layer of stacked plate.

13. The back light module of claim 9, wherein said stacked plate is arranged on two side walls facing each other.

14. The back light module of claim 9, wherein said stacked plate is arranged on all side walls of said backplane.

15. The back light module of claim 9, wherein said stacked plate is arranged on the outer surfaces of the side walls.

16. The back light module of claim 9, wherein said backplane is a plastic backplane and said stacked plate is a metal plate.

17. AN LCD device comprises the back light module of claim 9, said back light module comprises the backplane comprising the backplane surface, the side walls arranged on the sides of the backplane surface, and at least one layer of stacked plate fixed to the side walls in a stacked mode.

18. The LCD device of claim 17, wherein said stacked plate is folded edges formed by bending of the side walls.

19. The LCD device of claim 17, wherein the height of said stacked plate corresponds to that of said side walls.

20. The LCD device of claim 17, wherein said backplane comprises one layer of stacked plate.

21. The LCD device of claim 17, wherein side stacked plate is arranged on two side walls facing each other.

22. The LCD device of claim 17, wherein said stacked plate is arranged on all side walls of said backplane.

23. The LCD device of claim 17, wherein said stacked plate is arranged on the outer surfaces of the side walls.

24. The LCD device of claim 17, wherein said backplane is a plastic backplane and said stacked plate is a metal plate.
